(19) United States
(12) Patent Application Publication
(10) Pub. No.: US 2010/0041214 A1
(43) Pub. Date: Feb. 18, 2010

(54) Single crystal substrate and method of fabricating the same

(76) Inventors: Hans S. Cho, Seoul (KR); Takashi Noguchi, Seongnam-si (KR); Wenxu Xianyu, Yongin-si (KR); Xiaoxin Zhang, Yongin-si (KR); Huaxiang Yin, Yongin-si (KR)

Correspondence Address: HARNESS, DICKEY & PIERCE, P.L.C., P.O. BOX 8910, RESTON, VA, 20195, US

(21) Appl. No.: 12/461,315

(22) Filed: Aug. 7, 2009

Related U.S. Application Data
(62) Division of application No. 11/289,311, filed on Nov. 30, 2005.
(60) Provisional application No. 60/657,711, filed on Mar. 3, 2005.

(30) Foreign Application Priority Data
Dec. 1, 2004 (KR) 10-2004-0099745
Feb. 26, 2005 (KR) 10-2005-0016266

(51) Int. Cl. H01L 21/20

(52) U.S. Cl. 438/481; 438/486; 257/E21.119; 257/E21.133

(57) ABSTRACT

A high quality single crystal substrate and a method of fabricating the same are provided. The method of fabricating a single crystal substrate includes: forming an insulator on a substrate; forming a window in the insulator, the window exposing a portion of the substrate; forming an epitaxial growth silicon or germanium seed layer on the portion of the substrate exposed through the window; depositing a silicon or germanium material layer, which are crystallization target material layers, on the epitaxial growth silicon 6r germanium seed layer and the insulator; and crystallizing the crystallization target material layer by melting and cooling the crystallization target material layer.

### CROSS-REFERENCE TO RELATED PATENT APPLICATIONS

This application is a divisional application of U.S. patent application Ser. No. 11/289,311, filed on Nov. 30, 2005, which claims the benefit of Korean Patent Application No. 10-2004-0099745, filed on Dec. 1, 2004, and No. 10-2005-0016266, filed on Feb. 26, 2005 in the Korean Intellectual Property Office, and U.S. Provisional Patent Application No. 60/657,711, filed on Mar. 3, 2005, in the U.S. Patent and Trademark Office, the entire disclosures of which are incorporated herein by reference.

### BACKGROUND OF THE DISCLOSURE

1. Field of the Disclosure

The present disclosure relates to a single crystal substrate and a method of fabricating the same, and more particularly, to a single crystal substrate and a single crystal germanium substrate.

2. Description of the Related Art

Single crystal silicon in wafer form, which is the mainstream material for wafers in the semiconductor industry, places a limit on the performance as transistors become smaller. In order to overcome the limitation, silicon-on-insulator (SOI), which has a single crystal silicon layer on an insulator, has been developed. SOI can improve the performance of devices without shrinking the dimensions of the device.

SOI is a high-mobility, single crystal silicon substrate and is a low-power consuming material that can reduce a parasitic capacitance and a short-channel effect, especially a cross-talk between devices. However, the manufacturing cost of a SOI is high.

A method of fabricating a SOI wafer, which is called smart cut, includes an annealing process performed at a high temperature of approximately 1000° C. The method includes coating an oxide layer on an initial bare wafer having a predetermined thickness by heat treatment, forming a boundary layer by injecting hydrogen ions (H⁺) as impurities underneath a surface of the wafer, bonding the wafer to a separate substrate, separating the boundary layer such that a silicon layer having a predetermined thickness remains on the substrate, and performing high-temperature annealing, etc.

The temperature of the thermal oxidation process reaches 900° C. or higher, and the temperature of the annealing process reaches up to approximately 1100° C. Such high-temperature processes may damage the substrate. Thus, such high-temperature processes in the conventional SOI wafer manufacturing method limit materials for substrates which can be used in the high-temperature processes. Even though a substrate made of a material that is durable at a high temperature is used, the substrate may be thermally impacted.

A semiconductor device manufactured from such a thermally impacted substrate is likely to have natural defects and a low yield. Furthermore, the processes of manufacturing SOI are difficult, and the cost is high. Moreover, the quality of a SOI layer is limited even at the high cost, thereby making it difficult to manufacture high-quality semiconductor devices.

### SUMMARY OF THE DISCLOSURE

The present invention may provide a single crystal substrate that can be readily fabricated at low cost, and a method of fabricating the single crystal substrate.

According to an aspect of the present invention, there may be provided a single crystal substrate including: a substrate; an insulator formed on the substrate and having a window exposing a portion of the substrate; a selective epitaxial growth layer formed on the portion of the substrate exposed through the window; and a single crystal layer formed on the insulator and the selective epitaxial growth layer, the single crystal layer being crystallized using the selective epitaxial growth layer as a crystallization seed layer.

The substrate may be one of a sapphire substrate, a silicon substrate, and a germanium substrate.

The substrate may be one of the sapphire substrate and a silicon substrate, and then the single crystal is silicon.

The substrate may be a germanium substrate, and then the single crystal is a germanium single crystal.

The insulator may be a Si0₂ insulating layer, and the insulator may include an Si0₂ insulating layer and an SiN_{X} layer stacked on the Si0₂ insulating layer.

A plurality of windows and single crystal layers may be formed, and a boundary may exist between adjacent single crystal layers.

According to another aspect of the present invention, there is provided a method of fabricating a single crystal substrate, the method including: forming an insulator on a substrate; forming a window in the insulator, the window exposing a o portion of the substrate; forming an epitaxial growth seed layer on the portion of the substrate exposed through the window; depositing a crystallization target material layer on the epitaxial growth seed layer and the insulator; and crystallizing the crystallization target material layer by melting and cooling the crystallization target material layer.

The substrate may be one of a sapphire substrate, a silicon substrate, and a germanium substrate. The insulator may be one of a Si0₂ layer and a SiN_{X} layer, and the insulator may include a Si0₂ layer and a SiN_{X} layer on the Si0₂ layer.

The crystallization target material layer may be an amorphous silicon layer or an amorphous germanium layer.

The substrate may be a germanium substrate, and then the single crystal is germanium single crystal.

### BRIEF DESCRIPTION OF THE DRAWINGS

The above and other features and advantages of the present invention will be described in detailed exemplary embodiments thereof with reference to the attached drawings in which:

FIG. 1A is a schematic cross-sectional view of a first example of a single crystal silicon substrate according to the present invention;

FIG. 1B is a schematic cross-sectional view of a second example of a single crystal silicon substrate according to the present invention;

FIG. 2A is a schematic cross-sectional view of a first example of a single crystal germanium substrate according to the present invention;

FIG. 2B is a schematic cross-sectional view of a second example of a single crystal germanium substrate according to the present invention; and

FIGS. 3A through 3G are process parameter views with respect to a method of fabricating a single crystal silicon substrate according to the present invention.

### DETAILED DESCRIPTION OF THE EXEMPLARY EMBODIMENTS

Hereinafter, embodiments of a single crystal substrate and a method of fabricating the single crystal substrate according to the present invention will be described in detail with reference to accompanying drawings. A single crystal substrate according to the present invention may be a single crystal silicon substrate or a single crystal germanium substrate.

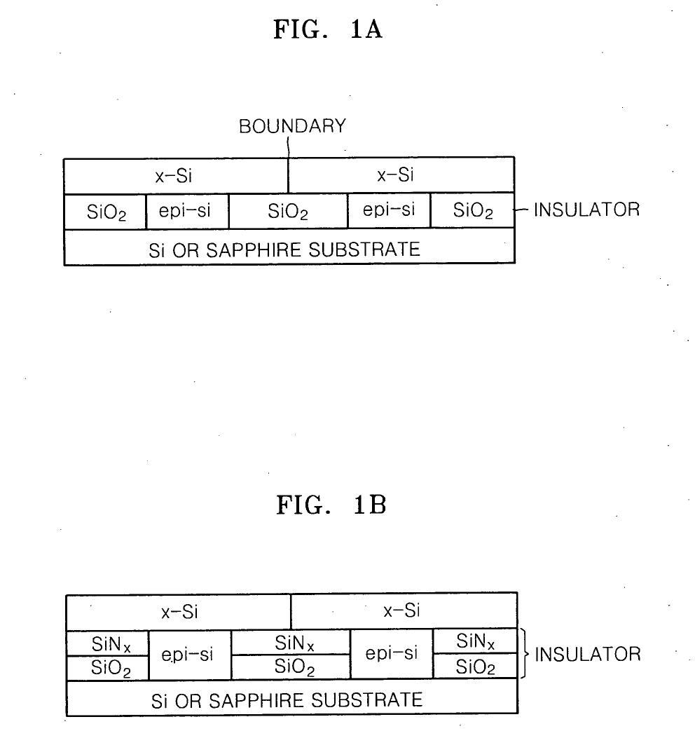

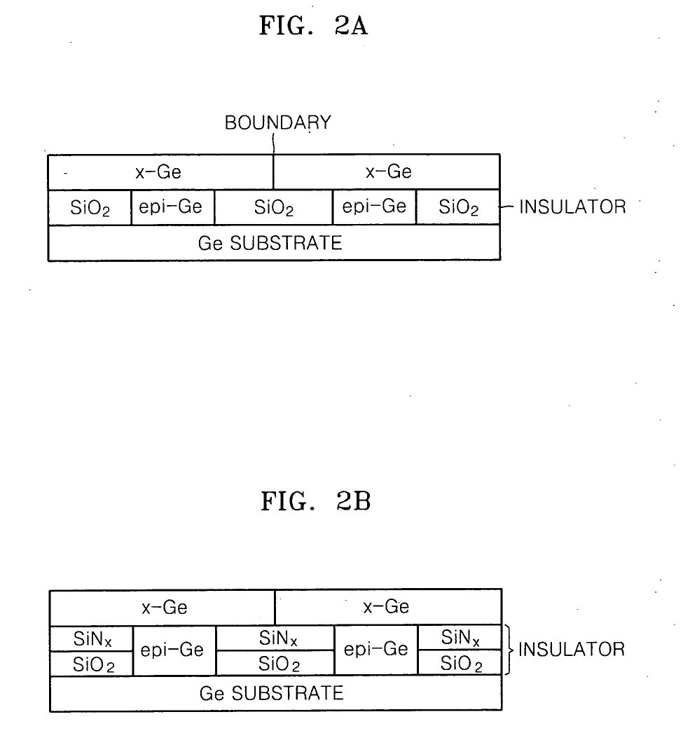

FIG. 1A is a schematic cross-sectional view of a first example of a single crystal silicon wafer according to the present invention.

A Si0₂ insulator is formed on a silicon substrate or a sapphire substrate.

A window or an opening is formed in the insulator, and a silicon (epi-Si) layer is formed in the window or opening by selective epitaxial growth.

Single crystal silicon (x-Si) layers are formed on the Si0₂ insulator and the epi-Si layer. The x-Si layers are obtained through the crystallization of amorphous silicon. Here, the epi-Si layer acts as seeds for the crystallization.

The crystallization of the x-Si layer begins with a plurality of seeds, and a boundary between adjacent x-Si layers is located in the middle of the insulator between the x-Si layers. The x-Si layers on both sides of the boundary located on the insulator have highly uniform crystalline structures, and high quality devices can be manufactured from the x-Si layers.

FIG. 1B is a schematic cross-sectional view of a second example of a single crystal silicon wafer according to the present invention.

In the single crystal silicon substrate according to the present embodiment, the Si0₂ insulator has a double layer structure, not the single layer structure. That is, insulators in which a Si0₂ layer and a SiN, layer are stacked are formed as islands on a silicon substrate or a sapphire substrate. A window (W) or an opening for selective epitaxial growth is formed between adjacent insulators having the double layer structures, and a Si (epi-Si) layer is formed in the window or opening. In addition, a plurality of x-Si layers (two in the present example) with boundaries therebetween are formed on the Si0₂ insulators and the epi-Si layers.

The SiN_{X} layer, which is a feature of the present embodiment, may be formed of Si₃N₄. This material layer suppresses the agglomeration of crystal Si by surface tension during the crystallization of the silicon, so that high-quality single crystal silicon (x-Si) can be obtained. Therefore, any material having a lower interface energy with respect to Si0₂, such as Si₃N₄, can be used as a material for the layer on the Si0₂ layer. The particularly preferred material for the layer on the Si0₂ layer is Si₃N₄.

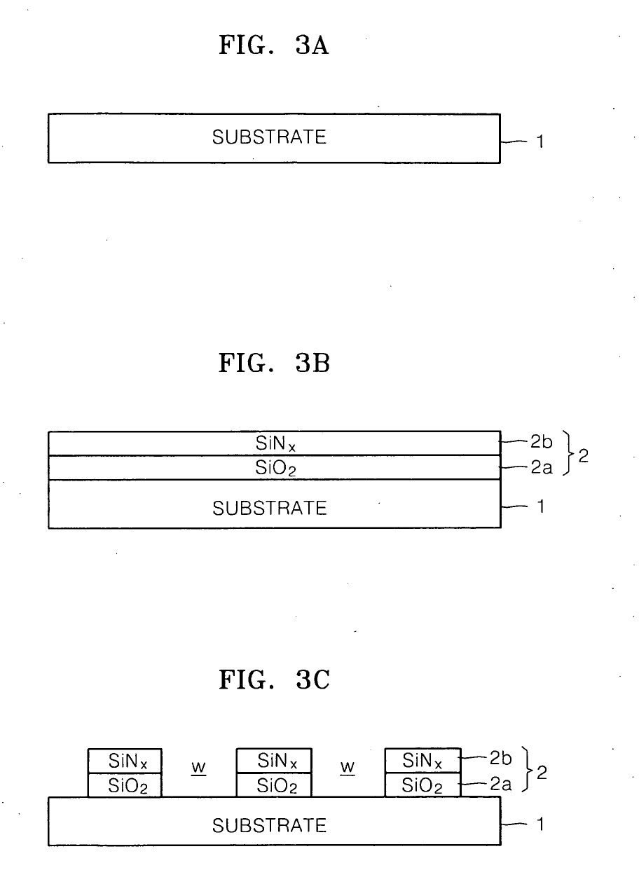

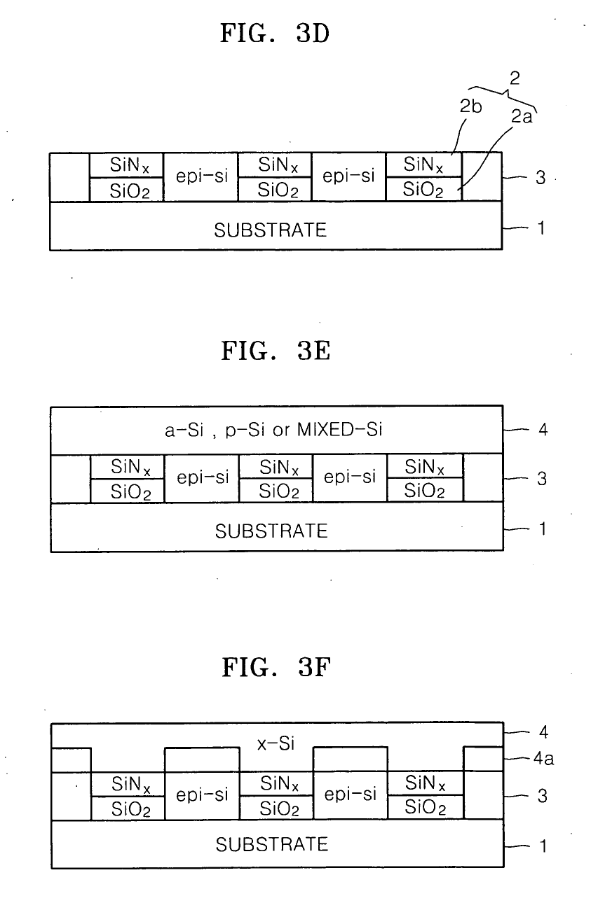

FIG. 2 illustrates a first example of a germanium substrate according to the present invention, and FIG. 2B illustrates a second example of a germanium substrate according to the present invention.

Referring to FIG. 2A, a Si0₂ insulator is formed on the germanium substrate, and a window or opening is formed in the insulator. A germanium (epi-Ge) layer is formed in the window or opening by selective epitaxial growth.

Single crystal germanium (x-Ge) layers are formed on the Si0₂ insulator and the epi-Ge layer. Like the single crystal silicon (x-Si) layers described in the above embodiment, the x-Ge layers are obtained through the crystallization of amorphous germanium. Here, the epi-Ge layers are used as seeds for the crystallization.

The crystallization of the x-Ge layers begins with a plurality of seeds, and thus a boundary exists between adjacent x-Ge layers. The x-Ge layers formed on both sides of the boundary on each of the insulators have highly uniform crystalline structures.

Referring to FIG. 2B, in the single crystalline germanium substrate according to the present example, the insulator has a double layer structure, not the Si0₂ single layer structure. That is, insulators in which a Si0₂ layer and a SiNₓ layer are stacked are formed as islands on a germanium substrate. A window (W) or an opening for selective epitaxial growth is formed between adjacent insulators having the double layer structures, and a Ge (epi-Ge) layer is formed in the window or opening. In addition, a plurality of x-Ge layers (two in the present example) with boundaries therebetween are formed on the Si0₂ insulators and the epi-Ge layers.

A method of fabricating a single crystal silicon substrate having such a structure as described above is described hereafter. A method of fabricating a single crystal germanium substrate can be easily derived from the single crystal silicon substrate fabrication method. When fabricating the single crystal silicon substrate, a silicon wafer or a sapphire substrate is used. When fabricating the single crystal germanium substrate, a germanium wafer is used. Seeds and materials to be crystallized are silicon or germanium.

Hereinafter, a method of fabricating a single crystal silicon substrate according to the present invention is described.

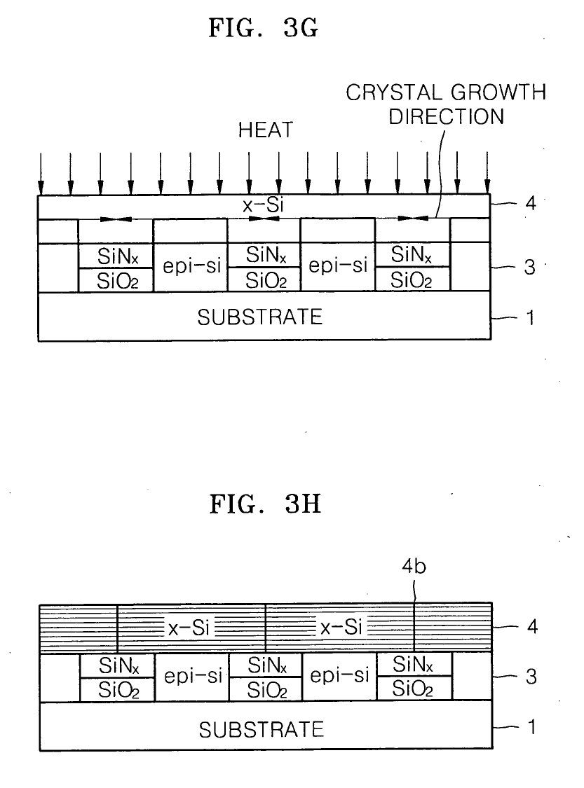

Referring to FIG. 3A, a substrate 1 is prepared. A silicon wafer or a sapphire substrate can be used as the substrate 1.

Referring to FIG. 3B, an insulator 2 having a double layer structure, i.e., in which a Si0₂ layer and a Si₃N₄ layer are sequentially stacked, is formed on the substrate 1 using a chemical vapor deposition (CVD) method or a sputtering method.

Referring to FIG. 3C, the insulator 2 is patterned into islands, thereby resulting in windows (W) between the insulators 2. The windows (W) expose parts of the surface of the substrate, which can be used as epitaxial growth seed surfaces in a subsequent crystal growing process.

Referring to FIG. 3D, epi-Si layers 3 are formed on the surfaces of the substrate 1 exposed through the windows W between the insulators 2 using a selective epitaxial growth method. Here, the heights of the epi-Si layers 3 are determined to be equal to or higher than the heights of the insulators 2.

Referring to FIG. 3E, a silicon material layer 4 is formed on the entire surface of the substrate 1, i.e., over the insulators 2 and the epi-Si layers 3. The silicon material layer 4 may be amorphous silicon (a-Si), polycrystalline silicon (p-Si), or mixed Si including both a-Si and p-Si, which appears due to the difference in silicon deposition method.

Referring to FIG. 3F, the resultant structure is annealed in a general furnace to induce solid phase crystallization. In the annealing process, the Si layers are densified and gas that remains in the Si layers is removed. In addition, crystallized regions 4a appear on the epi-Si layers 3 through the operation of the annealing process.

Referring to FIG. 3G, the silicon material layer 4 is heated at a melting temperature and is cooled down to crystallize the silicon material. An excimer laser can be used as a heat source. That is, the silicon material 4 is melted by an excimer laser annealing (ELA) process, and then is cooled down to crystallize or re-crystallize the silicon material. The crystal growth starts from upper portions of the epi-Si layers 3 functioning as seed layers and proceeds in a lateral direction parallel to the substrate, as indicated by arrows.

FIG. 3H illustrates the state of completed crystal growth. Through the use of the melting and cooling processes described above, a plurality of single crystal silicon (x-Si) layers 4 with boundaries 4b therebetween are formed on the surface of the substrate 1.

As described above, a method of fabricating a single crystal germanium substrate can be easily derived from the above-describe method of fabricating a single crystal silicon substrate. The processing conditions are similar to those used to form the single crystal silicon substrate. Instead of the silicon substrate or sapphire substrate, a germanium substrate is used. All the seed layers and materials to be crystallized are germanium.

The complete crystallization of single crystal silicon is related with the gap between epi-Si layers or the width of Si0₂ insulators. Thus, single crystal silicon can be successfully crystallized by reducing the gap between epi-Si layers or the width of Si0₂ insulators. This is because there is a limit to the lateral growth of crystal by laser melting and cooling processes. When the width of an insulator is two times greater than the width of the insulator in the present invention, in center portions of the insulators where lateral crystallization cannot reach, polycrystalline silicon is formed through frequent nucleation of liquefied silicon.

As described above, according to the present invention, a single crystal silicon substrate and a single crystal germanium substrate can be easily fabricated at low cost. Therefore, devices can be manufactured at low cost using a method of fabricating such a single crystal substrate according to the present invention.

The present invention can be applied to various fields in which a single crystal silicon or germanium substrate having an SOI structure is required.

The method of fabricating a single crystal substrate according to the present invention can be applied to TFT and devices using silicon, for example, solar batteries.

While the present invention has been particularly shown and described with reference to exemplary embodiments thereof, it will be understood by those of ordinary skill in the art that various changes in form and details may be made therein without departing from the spirit and scope of the present invention as defined by the following claims.

1.-5. (canceled)

6. A method of fabricating a single crystal substrate, the method comprising:
forming an insulator on a substrate;
forming a window in the insulator, the window exposing a portion of the substrate;
forming an epitaxial growth seed layer on the portion of the substrate exposed through the window;
depositing a crystallization target material layer on the epitaxial growth seed layer and the insulator; and
crystallizing the crystallization target material layer by melting and cooling the crystallization target material layer.

7. The method of claim 6, wherein the substrate is one of a sapphire substrate, a silicon substrate, and a germanium substrate.

8. The method of claim 6, wherein the insulator is one of a Si0₂ layer and a SiNₓ layer.

9. The method of claim 6, wherein the insulator includes a Si0₂ layer and a SiNₓ layer on the Si0₂ layer.

10. The method of claim 6, wherein the crystallization target material layer is an amorphous silicon layer or an amorphous germanium layer.

11. The method of claim 6, wherein the crystallization target material layer is a polycrystalline silicon layer or a poly crystalline germanium layer.

12. The method of claim 6, wherein the crystallization target material layer has a material structure including both amorphous and polycrystalline structures.

13. The method of claim 6, wherein the melting the crystallization target material layer is performed using an excimer laser annealing (ELA) process.

14. The method of claim 6, wherein the melting the insulator is performed using a chemical vapor deposition (CVD) method or a sputtering method.

15. The method of claim 6, further comprising annealing the crystallization target material layer between the depositing and the crystallizing of the crystallization target material layer.
